(19) United States
(12) Patent Application Publication
(10) Pub. No.: US 2025/0048562 A1
(43) Pub. Date: Feb. 6, 2025

(54) WIRING SUBSTRATE

(71) Applicant: IBIDEN CO., LTD., Ogaki (JP)

(72) Inventors: Masashi KUWABARA, Ibi-gun (JP); Susumu KAGOHASHI, Ogaki (JP); Jun SAKAI, Ogaki (JP); Kyohei YOSHIKAWA, Ogaki (JP); Takuya INISHI, Ibi-gun (JP)

(73) Assignee: IBIDEN CO., LTD., Ogaki (JP)

(21) Appl. No.: 18/789,154

(22) Filed: Jul. 30, 2024

(30) Foreign Application Priority Data
Aug. 1, 2023 (JP) 2023-125272

(51) Int. Cl. H05K 3/38; H05K 1/03; H05K 1/11; H05K 3/00; H05K 3/16; H05K 3/26; H05K 3/40

(52) U.S. Cl. CPC H05K 3/388; H05K 1/0306; H05K 1/115; H05K 3/0055; H05K 3/16; H05K 3/26; H05K 3/4038; H05K 2201/0209; H05K 2201/0263; H05K 2201/032; H05K 2201/0338; H05K 2201/09536; H05K 2201/09563; H05K 2201/096; H05K 2203/072; H05K 2203/0723; H05K 2203/0789; H05K 2203/107; H05K 2203/143

(57) ABSTRACT

A wiring substrate includes a core substrate including a glass substrate and a through-hole conductor, a resin insulating layer having an opening extending through the resin insulating layer, a conductor layer including a seed layer and an electrolytic plating layer on the seed layer, and a via conductor formed in the opening such that the via conductor electrically connects to the through-hole conductor in the core substrate and includes the seed layer and electrolytic plating layer extending from the conductor layer. The resin insulating layer includes resin and inorganic particles including first and second particles such that the first particles are partially embedded in the resin and that the second particles are embedded in the resin, the first particles have first portions protruding from the resin and second portions embedded in the resin respectively, the surface includes the resin and exposed surfaces of the first portions exposed from the resin.

### CROSS-REFERENCE TO RELATED APPLICATIONS

The present application is based upon and claims the benefit of priority to Japanese Patent Application No. 2023-125272, filed Aug. 1, 2023, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2015-133473 describes a multilayer substrate having a core formed of a glass material. The entire contents of this publication are incorporated herein by reference.

### SUMMARY OF THE INVENTION

According to one aspect of the present invention, a wiring substrate includes a core substrate including a glass substrate and a through-hole conductor penetrating through the glass substrate, a resin insulating layer formed on the core substrate and having an opening extending through the resin insulating layer, a conductor layer formed on a surface of the resin insulating layer and including a seed layer formed by sputtering and an electrolytic plating layer formed on the seed layer, and a via conductor formed in the opening of the resin insulating layer such that the via conductor electrically connects to the through-hole conductor in the core substrate and includes the seed layer and electrolytic plating layer extending from the conductor layer. The resin insulating layer includes resin and inorganic particles including first particles and second particles such that the first particles are partially embedded in the resin and that the second particles are embedded in the resin, and the resin insulating layer is formed such that the first particles have first portions protruding from the resin and second portions embedded in the resin respectively and that the surface includes the resin and exposed surfaces of the first portions exposed from the resin.

According to another aspect of the present invention, a method of manufacturing a wiring substrate includes forming a core substrate including a glass substrate and a through-hole conductor penetrating through the glass substrate, forming a resin insulating layer on the core substrate such that the resin insulating layer has an opening extending through the resin insulating layer, forming a conductor layer on a surface of the resin insulating layer such that the conductor layer includes a seed layer formed by sputtering and an electrolytic plating layer formed on the seed layer, and forming a via conductor in the opening of the resin insulating layer such that the via conductor electrically connects to the through-hole conductor in the core substrate and includes the seed layer and electrolytic plating layer extending from the conductor layer. The resin insulating layer includes resin and inorganic particles including first particles and second particles such that the first particles are partially embedded in the resin and that the second particles are embedded in the resin, and the resin insulating layer is formed such that the first particles have first portions protruding from the resin and second portions embedded in the resin respectively and that the surface includes the resin and exposed surfaces of the first portions exposed from the resin.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a wiring substrate according to an embodiment of the present invention;

FIG. 2 is an enlarged cross-sectional view schematically illustrating a part of a wiring substrate according to an embodiment of the present invention;

FIG. 3A is an enlarged cross-sectional view schematically illustrating a part of a wiring substrate according to an embodiment of the present invention;

FIG. 3B is an enlarged cross-sectional view schematically illustrating a part of an inner wall surface;

FIG. 3C is an enlarged cross-sectional view schematically illustrating a part of a seed layer;

FIG. 4 is a cross-sectional photograph schematically showing a part of a wiring substrate according to an embodiment of the present invention;

FIG. 5A is a cross-sectional view schematically illustrating a method for manufacturing a wiring substrate according to an embodiment of the present invention;

FIG. 5B is a cross-sectional view schematically illustrating a method for manufacturing a wiring substrate according to an embodiment of the present invention;

FIG. 5C is a cross-sectional view schematically illustrating a method for manufacturing a wiring substrate according to an embodiment of the present invention;

FIG. 5D is a cross-sectional view schematically illustrating a method for manufacturing a wiring substrate according to an embodiment of the present invention;

FIG. 5E is a cross-sectional view schematically illustrating a method for manufacturing a wiring substrate according to an embodiment of the present invention;

FIG. 5F is a cross-sectional view schematically illustrating a method for manufacturing a wiring substrate according to an embodiment of the present invention;

FIG. 5G is a cross-sectional view schematically illustrating a method for manufacturing a wiring substrate according to an embodiment of the present invention;

FIG. 5H is an enlarged cross-sectional view schematically illustrating a method for manufacturing a wiring substrate according to an embodiment of the present invention;

FIG. 5I is a cross-sectional view schematically illustrating a method for manufacturing a wiring substrate according to an embodiment of the present invention;

FIG. 5J is an enlarged cross-sectional view schematically illustrating a method for manufacturing a wiring substrate according to an embodiment of the present invention;

FIG. 5K is a cross-sectional view schematically illustrating a method for manufacturing a wiring substrate according to an embodiment of the present invention;

FIG. 5L is an enlarged cross-sectional view schematically illustrating a method for manufacturing a wiring substrate according to an embodiment of the present invention;

FIG. 5M is a cross-sectional view schematically illustrating a method for manufacturing a wiring substrate according to an embodiment of the present invention;

FIG. 6 is a cross-sectional view schematically illustrating a method for manufacturing a wiring substrate of a modified example according to an embodiment of the present invention; and

FIG. 7 is a cross-sectional view schematically illustrating a method for manufacturing a wiring substrate of a modified example according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Embodiment

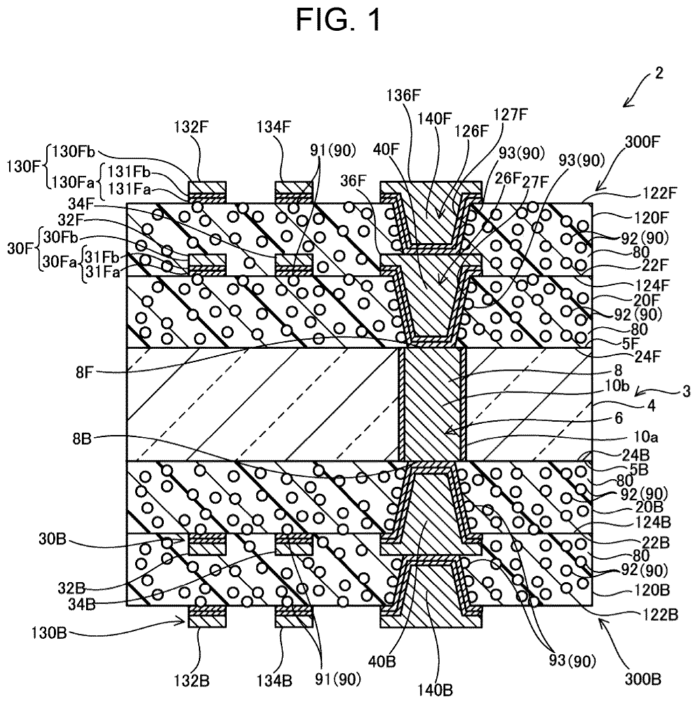

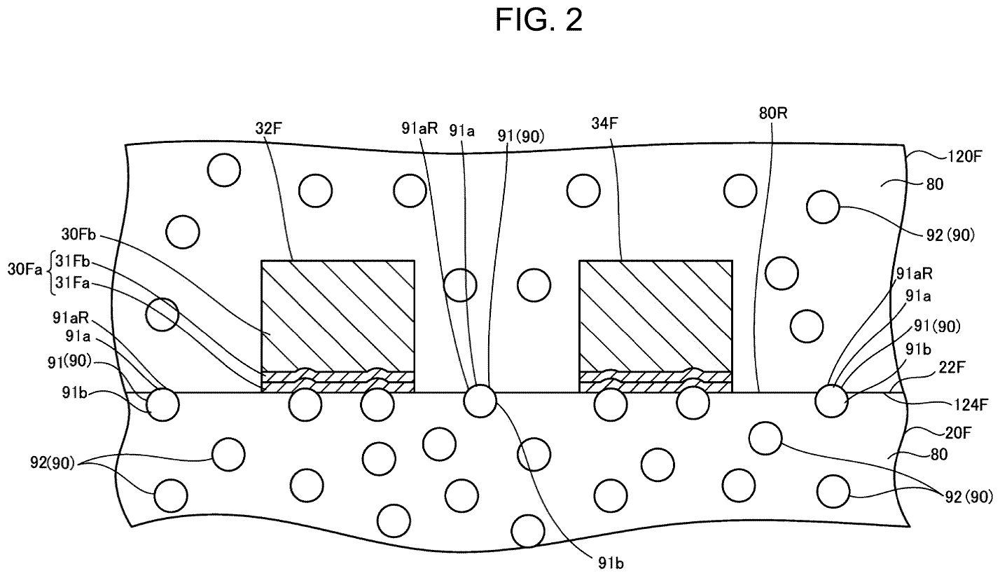

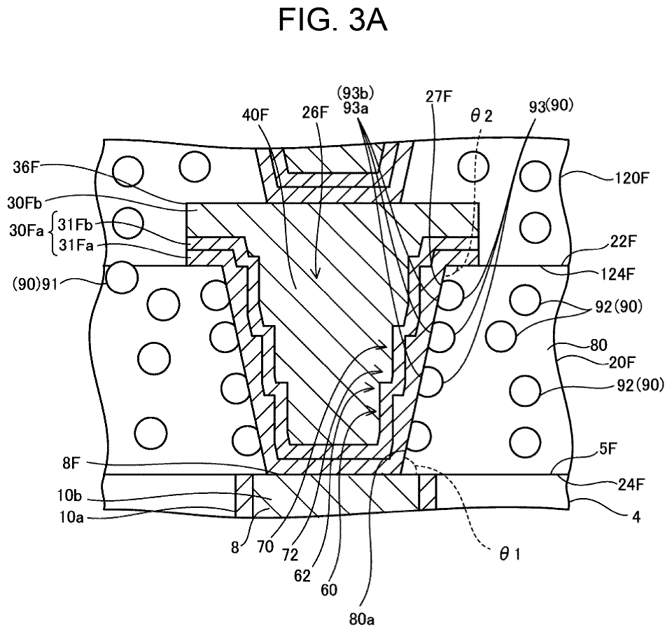

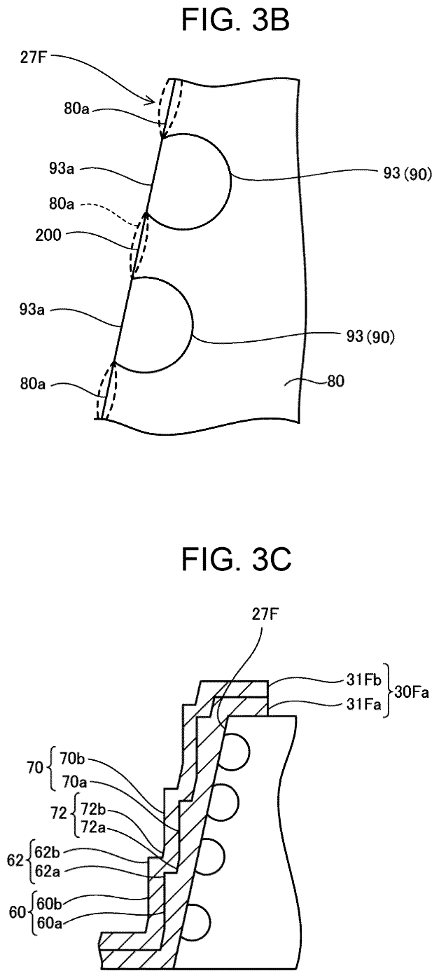

FIG. 1 is a cross-sectional view illustrating a wiring substrate 2 of an embodiment. FIGS. 2 and 3A are each an enlarged cross-sectional view illustrating a part of the wiring substrate 2 of the embodiment. As illustrated in FIG. 1, the wiring substrate 2 includes a core substrate 3, a front side build-up layer (300F), and a back side build-up layer (300B).

The core substrate 3 includes a substrate 4, through holes 6, and through-hole conductors 8. The substrate 4 has a front surface (5F) and a back surface (5B) on the opposite side with respect to the front surface (5F). The substrate 4 is formed of glass. The through holes 6 penetrate the substrate 4. The through holes 6 each have a substantially cylindrical shape. The through holes 6 each have a substantially constant diameter. It is also possible that the through holes 6 each have a substantially truncated cone shape. It is also possible that the through holes 6 each have a shape obtained by connecting two substantially conical shapes. The two cones are a front surface side cone and a back surface side cone. A bottom surface of the front surface side cone is positioned on the front surface (5F), and a bottom surface of the back surface side cone is positioned on the back surface (5B). In this case, a side surface of each of the through holes 6 is formed of a surface tapering from the front surface (5F) toward the back surface (5B) and a surface tapering from the back surface (5B) toward the front surface (5F).

The through-hole conductors 8 are respectively formed in the through holes 6. The through-hole conductors 8 are mainly formed of copper. The through-hole conductors 8 include a seed layer (10a) formed on inner wall surfaces of the through holes 6 and an electrolytic plating layer (10b) formed on the seed layer (10a). The electrolytic plating layer (10b) fills the through holes 6. The seed layer (10a) is formed by electroless plating. The through-hole conductors 8 each have an upper end (8F) and a lower end (8B). A surface of the upper end (8F) and the front surface (5F) form substantially the same flat surface. A surface of the lower end (8B) and the back surface (5B) form substantially the same flat surface. The upper end (8F) is exposed from the front surface (5F). The lower end (8B) is exposed from the back surface (5B).

The front side build-up layer (300F) is formed on the front surface (5F) of the substrate 4. The front side build-up layer (300F) includes front side resin insulating layers, front side conductor layers, and front side via conductors that penetrate the front side resin insulating layers. The front side conductor layers and the front side via conductors are electrically connected to the through-hole conductors 8. The front side resin insulating layers and the front side conductor layers are alternately laminated. The front side resin insulating layers in FIG. 1 are a first resin insulating layer (20F) and a second resin insulating layer (120F). The front side conductor layers are a first conductor layer (30F) and a second conductor layer (130F). The front side via conductors are first via conductors (40F) and second via conductors (140F).

The first resin insulating layer (20F) has a first surface (22F) and a second surface (24F) on the opposite side with respect to the first surface (22F). The first resin insulating layer (20F) is formed on the front surface (5F) of the substrate 4 with the second surface (24F) facing the front surface (5F). In the example of FIG. 1, the second surface (24F) is in contact with the front surface (5F). The second surface (24F) is in contact with a part of the upper end (8F). No conductor circuit exists between the front surface (5F) and the second surface (24F). No conductor circuit is formed on the front surface (5F). The first resin insulating layer (20F) has first openings (26F) that respectively reach the upper ends (8F) of the through-hole conductors 8. The first openings (26F) each have an opening (top opening) on the first surface (22F) and an opening (bottom opening) on the second surface (24F). The top opening and the bottom opening each have a substantially circular shape. The bottom opening can expose the upper end (8F) and the front surface (5F) at the same time. In this case, the front surface (5F) around the upper end (8F) is exposed. It is also possible that the bottom opening exposes a part of the upper end (8F) and the front surface (5F) around the part (first example). It is also possible that the bottom opening exposes the entire upper end (8F) and the front surface (5F) around the upper end (8F) (second example). As illustrated in FIG. 1, the bottom opening can expose only the upper end (8F) (third example). Two examples among the first example, the second example and the third example may be mixed. All of the first example, the second example and the third example may be mixed. It is preferable that the first example and the third example are mixed. In this case, the upper ends (8F) of some of the through-hole conductors 8 are exposed by the openings of the first example, and the upper ends (8F) of the remaining through-hole conductors are exposed by the openings of the third example. The first resin insulating layer (20F) is formed of a resin 80 and a large number of inorganic particles 90 dispersed in the resin 80. The resin 80 is an epoxy resin. Examples of the resin include a thermosetting resin and a photocurable resin. The inorganic particles 90 are glass particles. It is also possible that the inorganic particles 90 are alumina particles. A content of the inorganic particles 90 in the first resin insulating layer (20F) is 75 wt % or more.

As illustrated in FIGS. 1 and 2, the inorganic particles 90 include first inorganic particles 91 that are partially embedded in the resin 80 and second inorganic particles 92 that are embedded in the resin 80. The second inorganic particles are completely embedded in the resin 80. The first inorganic particles 91 and the second inorganic particles 92 have spherical shapes. As illustrated in FIG. 2, the first inorganic particles 91 are each formed of a first portion (91a) protruding from the resin 80 and a second portion (91b) embedded in the resin 80. The first surface (22F) of the first resin insulating layer (20F) is formed of an upper surface (80R) of the resin 80 and exposed surfaces (91aR) of the first portions (91a) exposed from the upper surface (80R) of the resin 80.

A ratio (R) of a volume of the first portions (91a) to a volume of the first inorganic particles 91 ((the volume of the first portions (91a))/(the volume of the first inorganic particles 91)) is greater than 0 and less than or equal to 0.4. The ratio (R) is preferably 0.2 or less. The ratio (R) is more preferably 0.1 or less. The ratio (R) is most preferably 0.05 or less. When the first portions (91a) protrude from the resin 80, the first surface (22F) of the first resin insulating layer (20F) has slight unevenness. However, the upper surface (80R) of the resin 80 is not roughened. The upper surface (80R) of the resin 80 forming the first surface (22F) of the first resin insulating layer (20F) is substantially flat. The upper surface (80R) of the resin 80 has substantially no recesses. Therefore, the first surface (22F) has substantially no recesses. The first surface (22F) has an arithmetic mean roughness (Ra) of less than 0.08 μm. The roughness (Ra) of the first surface (22F) is preferably 0.05 μm or less. The roughness (Ra) of the first surface (22F) is more preferably 0.03 μm or less. The upper surface (80R) of the resin 80 forming the first surface (22F) of the first resin insulating layer (20F) has an arithmetic mean roughness (Ra) of less than 0.08 μm. The roughness (Ra) of the upper surface (80R) of the resin 80 is preferably 0.05 μm or less. The roughness (Ra) of the upper surface (80R) of the resin 80 is more preferably 0.03 μm or less.

As illustrated in FIG. 3A, the inorganic particles 90 further include third inorganic particles 93 that form the inner wall surface of the opening (via conductor opening). The third inorganic particles 93 each have a shape obtained by cutting a sphere along a flat surface. The third inorganic particles 93 each have a shape obtained by cutting a second inorganic particle 92 with a plane. The third inorganic particles 93 each have a substantially spherical segment shape. The third inorganic particles 93 and the second inorganic particles 92 are different in shape. The third inorganic particles 93 and the first inorganic particles 91 are different in shape. The first inorganic particles 91 and the second inorganic particles 92 are similar in shape.

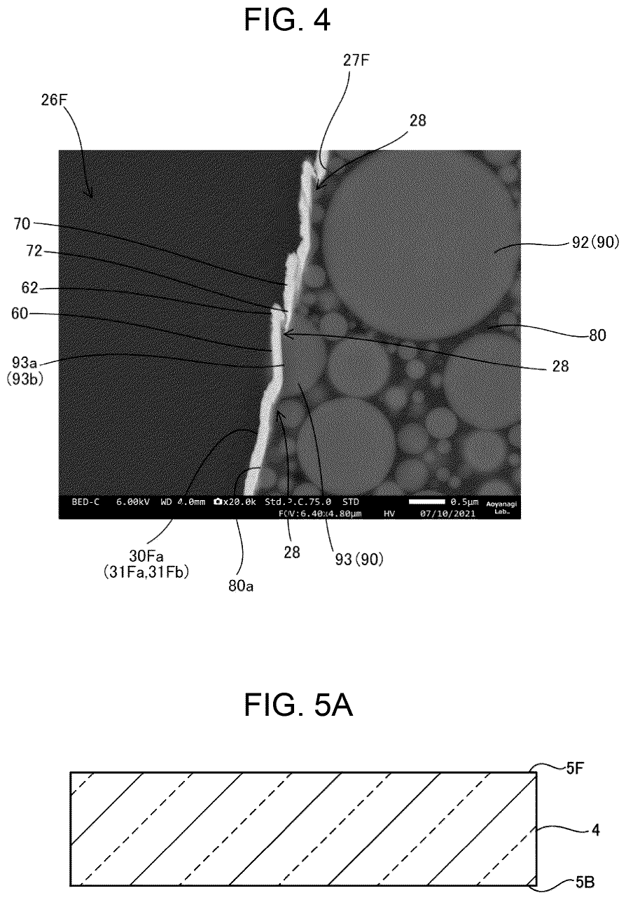

FIG. 4 is a cross-sectional photograph showing an example of an inner wall surface (27F) of each of the first openings (26F). As shown in FIGS. 3A and 4, the inner wall surface (27F) of each of the first openings (26F) is formed of the resin 80 and the third inorganic particles 93. The third inorganic particles 93 each have a flat part (93a). The flat parts (93a) form the inner wall surface (27F). The inner wall surface (27F) is formed of the resin 80 and the flat parts (93a). The flat parts (93a) and a surface of the resin 80 that forms the inner wall surface (27F) form substantially a common surface. No unevenness is formed on the resin 80 that forms the inner wall surface (27F). The surface of the resin 80 that forms the inner wall surface (27F) is smooth. No unevenness is formed on exposed surfaces (93b) of the flat parts (93a) (surfaces that form the inner wall surface 23). The exposed surfaces (93b) of the flat parts (93a) are smooth. The inner wall surface (27F) is formed smooth. The inner wall surface (27F) has an arithmetic mean roughness (Ra) of 1.0 μm or less. As shown in FIG. 4, steps 28 are formed at boundary parts between a surface (80a) of the resin 80 and the flat parts (93a) of the third inorganic particles 93. Sizes of the steps 28 are preferably 3.0 μm or less. The sizes of the steps 28 are more preferably 1.5 μm or less. The sizes of the steps 28 are even more preferably 0.5 m or less. For example, distances between the exposed surfaces (93b) and the surface (80a) of the resin 80 (the surface forming the inner wall surface (27F)) indicate the sizes of the steps 28. The exposed surfaces (93b) protrude from the surface (80a) of the resin 80. Or, the exposed surfaces (93b) are recessed from the surface (80a) of the resin 80. Protruding is preferable.

The flat parts (93a) of the third inorganic particles 93 substantially coincide with a surface obtained by extending the surface (80a) of the resin 80 formed around the third inorganic particles 93 (a surface that forms the inner wall surface (27F)). The flat parts (93a) drawn with substantially straight lines in FIGS. 1 and 3A each mean a flat surface. In the cross sections illustrated in FIGS. 1 and 3A, the flat parts (91a) are each a flat surface. It is also possible that the flat parts (93a) are not each a perfect flat surface. The flat parts (93a) are each substantially a flat surface and are each substantially a smooth surface.

FIG. 3B is an enlarged cross-sectional view illustrating a part of the inner wall surface (27F) in FIG. 3A. As illustrated in FIG. 3B, with respect to a reference surface 200 connecting the flat parts (91a) of two third inorganic particles 93 forming the inner wall surface (27F), the surface (80a) of the resin 80 positioned between the two third inorganic particles 93 may be recessed or protruding (see the dashed lines). Preferably, there are no other third inorganic particles 93 between the two third inorganic particles 93 that form the reference surface 200. A distance between the reference surface 200 and the surface (80a) of the resin 80 may be used as a representative value of the sizes of the steps 28.

As illustrated in FIG. 3A, the inner wall surface (27F) of each of the first openings (26F) is inclined. An angle (inclination angle) (01) between the front surface (5F) of the substrate 4 and the inner wall surface (27F) is 70 degrees or more and 85 degrees or less. An angle (inclination angle) (02) between the first surface (22F) of the first resin insulating layer (20F) and the inner wall surface (27F) is 95 degrees or more and 110 degrees or less.

In the cross-sections illustrated in FIGS. 1 and 3A, the first openings (26F) are illustrated to each have a substantially inverted trapezoidal shape. However, the actual first openings (26F) each have a substantially inverted truncated cone shape. Therefore, the actual inner wall surface (side wall) (27F) of each of the first openings (26F) is a substantially curved surface. That is, the common surface formed by the flat parts (93a) and the resin 80 includes the inner wall surface (side wall) (27F) formed as a substantially curved surface.

As illustrated in FIG. 1, the first conductor layer (30F) is formed on the first surface (22F) of the first resin insulating layer (20F). The first conductor layer (30F) includes a first signal wiring (32F), a second signal wiring (34F), and lands (36F). Although not illustrated in the drawings, the first conductor layer (30F) also includes conductor circuits other than the first signal wiring (32F), the second signal wiring (34F), and the lands (36F). The first signal wiring (32F) and the second signal wiring (34F) form a pair wiring. The first conductor layer (30F) is mainly formed of copper. The first conductor layer (30F) is formed of a seed layer (30Fa) and an electrolytic plating layer (30Fb) on the seed layer (30Fa). The seed layer (30Fa) is formed by sputtering. The seed layer (30Fa) is formed of a first layer (31Fa) on the first surface (22F) and a second layer (31Fb) on the first layer (31Fa). The first layer (31Fa) is in contact with the first surface (22F). The first layer (31Fa) and the second layer (31Fb) are formed by sputtering. Both are sputtered films.

The first layer (31Fa) is formed of an alloy containing copper and aluminum. The first layer (31Fa) may further contain a specific metal. Examples of the specific metal include nickel, zinc, gallium, silicon, and magnesium. The alloy preferably contains one type of specific metal, or two types of specific metals, or three types of specific metals. A content of aluminum in the alloy is 1.0 at % or more and 15.0 at % or less. An example of the specific metal is silicon. A content of the specific metal in the alloy is 0.5 at % or more and 10.0 at % or less. The first layer (31Fa) may contain impurities. Examples of the impurities include oxygen and carbon. The first layer (31Fa) can contain oxygen or carbon. The first layer (31Fa) can contain oxygen and carbon. In the embodiment, the alloy further contains carbon. A content of carbon in the alloy is 50 ppm or less. The alloy further contains oxygen. A content of oxygen in the alloy is 100 ppm or less. The values of the contents of the elements described above are examples. Among the elements forming the first layer (31Fa), copper has the largest content. The content of aluminum is the next largest. The content of the specific metal is less than the content of aluminum. Therefore, copper is a primary metal, aluminum is a first secondary metal, and the specific metal is a second secondary metal. A content of the impurities is smaller than the content of the specific metal. The first layer (31Fa) is formed of a copper alloy.

The second layer (31Fb) is formed of copper. A content of copper forming the second layer (31Fb) is 99.9 at % or more. The content of copper in the second layer (31Fb) is preferably 99.95 at % or more. The seed layer (30Fa) is formed of a copper alloy. The electrolytic plating layer (30Fb) is formed of copper. A content of copper forming the electrolytic plating layer (30Fb) is 99.9 at % or more. The content of copper in the electrolytic plating layer (30Fb) is preferably 99.95 at % or more.

The first resin insulating layer (20F) is formed on the glass substrate 4. Since glass is excellent in flatness, the first surface (22F) of the first resin insulating layer (20F) is also excellent in flatness. When no conductor circuit is formed between the front surface (5F) and the first resin insulating layer (20F), the first surface (22F) can follow the front surface (5F). The first surface (22F) can have similar flatness as the front surface (5F). In the embodiment, fine wirings can be formed on the first surface (22F). For example, the first conductor layer (30F) can have wirings having widths of 1.5 μm or more and 3.5 μm or less. A width of a space between adjacent wirings is 1.5 μm or more and 3.5 μm or less.

The first via conductors (40F) are respectively formed in the first openings (26F). The first via conductors (40F) electrically connect the through-hole conductors 8 to the first conductor layer (30F). The first via conductors (40F) electrically connect the through-hole conductors 8 to the lands (36F) of the first via conductors (40F). The first via conductors (40F) are formed of a seed layer (30Fa) and an electrolytic plating layer (30Fb) on the seed layer (30Fa). The seed layer (30Fa) forming the first via conductors (40F) and the seed layer (30Fa) forming the first conductor layer (30F) are common. The electrolytic plating layer (30Fb) forming the first via conductors (40F) and the electrolytic plating layer (30Fb) forming the first conductor layer (30F) are common. The seed layer (30Fa) forming the first via conductors (40F) is formed of a first layer (31Fa), which is formed on the inner wall surfaces (27F) of the first openings (26F) and on the upper ends (8F) of the through-hole conductors 8 exposed from the first openings (26F), and a second layer (31Fb) on the first layer (31Fa). The first layer (31Fa) forming the first via conductors (40F) and the first layer (31Fa) forming the first conductor layer (30F) are common. The second layer (31Fb) forming the first via conductors (40F) and the second layer (31Fb) forming the first conductor layer (30F) are common. In FIG. 1, the first via conductors (40F) are respectively connected to the upper ends (8F). The first layer (31Fa) is in contact with the upper ends (8F) of the through-hole conductors 8 and the inner wall surfaces (27F). The first via conductors (40F) are respectively directly formed on the upper ends (8F).

FIG. 3C is an enlarged cross-sectional view schematically illustrating a part of the seed layer (30Fa) on the inner wall surface (27F) of FIG. 3A. FIG. 4 shows an example of the seed layer (30Fa). The seed layer (30Fa) on the inner wall surface (27F) is in contact with the inner wall surface (27F). As shown in FIGS. 3A, 3C and 4, the seed layer (30Fa) forming the first via conductors (40F) has a substantially smooth first film 60 and a substantially smooth second film 70. The first film 60 and the second film 70 are electrically connected to each other. The first film 60 and the second film 70 are continuous. As shown in FIG. 4, a part of the first film 60 is formed on the second film 70. A leading end 60 of the first film 60 is formed on a trailing end 72 of the second film 70. The first film 60 and the second film 70 are formed at the same time. The seed layer (30Fa) covering the inner wall surface (27F) has a substantially step-shaped cross section.

As illustrated in FIG. 3C, the first layer (31Fa) of the seed layer (30Fa) has a first film (60a) and a second film (70a). The first film (60a) and the second film (70a) are electrically connected to each other. The first film (60a) and the second film (70a) are continuous. A leading end (62a) of the first film (60a) is formed on a trailing end (72a) of the second film (70a). The first layer (31Fa) covering the inner wall surface (27F) has a substantially step-shaped cross section. The first layer (31Fa) on the inner wall surface (27F) is in contact with the inner wall surface (27F).

The second layer (31Fb) of the seed layer (30Fa) has a first film (60b) and a second film (70b). The first film (60b) and the second film (70b) are electrically connected to each other. The first film (60b) and the second film (70b) are continuous. A leading end (62b) of the first film (60b) is formed on a trailing end (72b) of the second film (70b). The second layer (31Fb) formed on the inner wall surface (27F) has a substantially step-shaped cross section.

In the embodiment, a part of the first film 60 is laminated on the second film 70. A part of the first film 60 overlaps the second film 70. The leading end 62 of the first film 60 is laminated on the trailing end 72 of the second film 70. The leading end 62 of the first film 60 overlaps the trailing end 72 of the second film 70.

The inner wall surface (27F) of the embodiment is formed as a substantially smooth surface. When the first layer (31Fa) follows the shape of the inner wall surface (27F), the first layer (31Fa) on the inner wall surface (27F) has a substantially smooth surface. The first layer (31Fa) has a linear cross-sectional shape. The seed layer (30Fa) on the inner wall surface (27F) has a substantially smooth surface. The seed layer (30Fa) has a linear cross-sectional shape. In this case, the electrolytic plating layer (30Fb) forming the first via conductors (40F) is formed on a smooth surface. For example, when the wiring substrate 2 is subjected to a large impact, peeling occurs between the first layer (31Fa) on the inner wall surface (27F) and the second layer (31Fb) on the first layer (31Fa). Or, peeling occurs between the seed layer (30Fa) on the inner wall surface (27F) and the electrolytic plating layer (30Fb) forming the first via conductors (40F). In contrast, the seed layer (30Fa) and the first layer (31Fa) in the embodiment each have a step-shaped cross section. Therefore, peeling is unlikely to occur.

When the via conductor openings expose the front surface (5F), the first layer (31Fa) is in contact with the glass substrate 4. The openings of the first example and the openings of the second example expose the front surface (5F). Further, the openings of the first example and the openings of the second example expose the upper ends (8F). Since the first layer (31Fa) contains aluminum and glass contains oxygen, it is thought that bonding strength between the first layer (31Fa) and the substrate 4 is increased. Further, when the first layer (31Fa) contains silicon, the first layer (31Fa) and the substrate 4 contain the same element (silicon). It is thought that the bonding strength between the first layer (31Fa) and the substrate 4 is further increased. When a part of the seed layer forming the via conductors is in contact with the glass substrate 4, the via conductors are unlikely to peel off from the through-hole conductors 8 even when the wiring substrate 2 is subjected to a thermal shock. It is preferable that the via conductors in contact with the upper ends (8F) are also in contact with the front surface (5F). In this case, a seed layer (for example, the first layer (31Fa)) forming such via conductors is in contact with both the upper ends (8F) and the front surface (5F). Similarly, it is preferable that the via conductors in contact with the lower ends (8B) are also in contact with the back surface (5B). In this case, a seed layer (for example, a first layer) forming such via conductors is in contact with both the lower ends (8B) and the back surface (5B). When an adhesive layer for bonding a resin insulating layer such as the first resin insulating layer (20F) and the substrate 4 is formed between the front surface (5F) and the second surface (24F), the adhesive layer may be a part of the resin insulating layer. The adhesive layer is included in the resin insulating layer. The adhesive layer includes an organic adhesive layer and an inorganic adhesive layer. The adhesive layer is formed of an insulating material.

The second resin insulating layer (120F) is formed on the first surface (22F) of the first resin insulating layer (20F) and on the first conductor layer (30F). The first conductor layer (30F) is formed between the second resin insulating layer (120F) and the first resin insulating layer (20F). The second resin insulating layer (120F) has a first surface (122F) and a second surface (124F) on the opposite side with respect to the first surface (122F). The second surface (124F) of the second resin insulating layer (120F) faces the first conductor layer (30F). Similar to the first resin insulating layer (20F), the second resin insulating layer (120F) is formed of the resin 80 and the inorganic particles 90 (the first inorganic particles 91, the second inorganic particles 92, and the third inorganic particles 93). Therefore, the material of the second resin insulating layer (120F) is similar to the material of the first resin insulating layer (20F). The first surface (122F) of the second resin insulating layer (120F) is similar to the first surface (22F) of the first resin insulating layer (20F). The first inorganic particles 91 forming the second resin insulating layer (120F) each have a first portion (91a) and a second portion (91b), and exposed surfaces (91aR) of the first portions (91a) form the first surface (122F) of the second resin insulating layer (120F). The first inorganic particles 91 in the first resin insulating layer (20F) and the first inorganic particles 91 in the second resin insulating layer (120F) have similar ratios (R).

The second resin insulating layer (120F) has second openings (126F) that expose the first conductor layer (30F). The second openings (126F) respectively expose the lands (36F). The second openings (126F) each have an inner wall surface (127F). The first openings (26F) and the second openings (126F) are similar. Therefore, the inner wall surface (27F) of each of the first openings (26F) and the inner wall surface (127F) of each of the second openings (126F) are similar.

The second conductor layer (130F) is formed on the first surface (122F) of the second resin insulating layer (120F). The second conductor layer (130F) includes a first signal wiring (132F), a second signal wiring (134F), and lands (136F). Although not illustrated in the drawings, the second conductor layer (130F) also includes conductor circuits other than the first signal wiring (132F), the second signal wiring (134F), and the lands (136F). The first signal wiring (132F) and the second signal wiring (134F) form a pair wiring. The second conductor layer (130F) and the first conductor layer (30F) are similar. Therefore, the second conductor layer (130F) is formed of a seed layer (130Fa) and an electrolytic plating layer (130Fb) on the seed layer (130Fa). The seed layer (130Fa) is formed of a first layer (131Fa) and a second layer (131Fb) on the first layer (131Fa). The first layer (131Fa) forming the second conductor layer (130F) is similar to the first layer (31Fa) forming the first conductor layer (30F). The second layer (131Fb) forming the second conductor layer (130F) is similar to the second layer (31Fb) forming the first conductor layer (30F). The electrolytic plating layer (130Fb) forming the second conductor layer (130F) is similar to the electrolytic plating layer (30Fb) forming the first conductor layer (30F).

The second via conductors (140F) are respectively formed in the second openings (126F). The second via conductors (140F) electrically connect the first conductor layer (30F) and the second conductor layer (130F). In FIG. 1, the second via conductors (140F) respectively electrically connect the lands (36F) to the lands (136F). The second via conductors (140F) and the first via conductors (40F) are similar. Therefore, the second via conductors (140F) are formed of a seed layer (130Fa) and an electrolytic plating layer (130Fb) on the seed layer (130Fa). The seed layer (130Fa) is formed of a first layer (131Fa) and a second layer (131Fb) on the first layer (131Fa). The first layer (131Fa) forming the second via conductors (140F) and the first layer (31Fa) forming the first conductor layer (30F) are similar. The second layer (131Fb) forming the second via conductors (140F) and the second layer (31Fb) forming the first conductor layer (30F) are similar. The electrolytic plating layer (130Fb) forming the second via conductors (140F) and the electrolytic plating layer (30Fb) forming the first conductor layer (30F) are similar. The first layer (131Fa) forming the second via conductors (140F) and the first layer (131Fa) forming the second conductor layer (130F) are common. The second layer (131Fb) forming the second via conductors (140F) and the second layer (131Fb) forming the second conductor layer (130F) are common. The electrolytic plating layer (130Fb) forming the second via conductors (140F) and the electrolytic plating layer (130Fb) forming the second conductor layer (130F) are common.

The back side build-up layer (300B) includes back side resin insulating layers, back side conductor layers, and back side via conductors that penetrate the back side resin insulating layers. The back side resin insulating layers and the back side conductor layers are alternately laminated. The back side conductor layers and the back side via conductors are electrically connected to the through-hole conductors 8. The back side resin insulating layers in FIG. 1 are a first resin insulating layer (20B) having a first surface (22B) and a second surface (24B) and a second resin insulating layer (120B) having a first surface (122B) and a second surface (124B). The back side conductor layers are a first conductor layer (30B) and a second conductor layer (130B). The first conductor layer (30B) and the second conductor layer (130B) include first signal wirings (32B, 132B) and second signal wirings (34B, 134B). The back side via conductors are first via conductors (40B) and second via conductors (140B).

The front side build-up layer (300F) and the back side build-up layer (300B) are similar. Therefore, the front side resin insulating layers forming the front side build-up layer (300F) and the back side resin insulating layers forming the back side build-up layer (300B) are similar. The back side resin insulating layers are each formed of a resin 80 and inorganic particles 90. The back side resin insulating layers contain the first inorganic 91, the second inorganic particles 92, and the third inorganic particles 93. The first surface of each of the resin insulating layers is formed of the upper surface (80R) of the resin 80 and the exposed surfaces (91aR) of the first portions (91a) exposed from the upper surface (80R) of the resin 80. The front side conductor layers and the back side conductor layers are similar. The openings for the front side via conductors and the openings for the back side via conductors are similar. The inner wall surface of each of the via conductor openings is formed of the surface (exposed surface) (80a) of the resin 80 and the exposed surfaces (93b) of the inorganic particles. The surface (80a) of the resin 80 and the exposed surfaces (93b) of the inorganic particles form a substantially common surface. The front side via conductors and the back side via conductors are similar.

Each side of the wiring substrate 2 has a length of 50 mm or more. The length of each side is preferably 100 mm or more. The length of each side is 250 mm or less. A length of a signal wiring formed according to the embodiment is 5 mm or more. The length of the signal wiring may be 10 mm or more and 20 mm or less.

### Method for Manufacturing Wiring Substrate

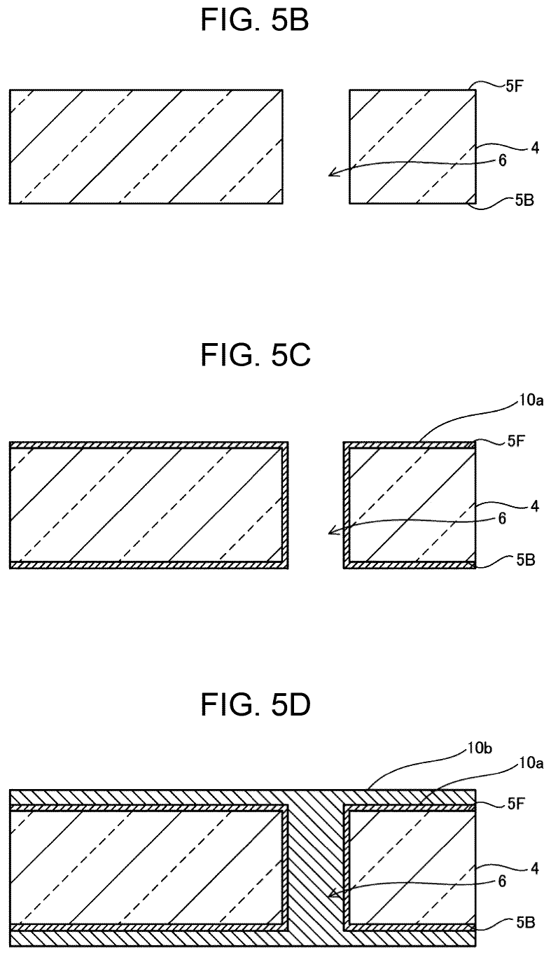

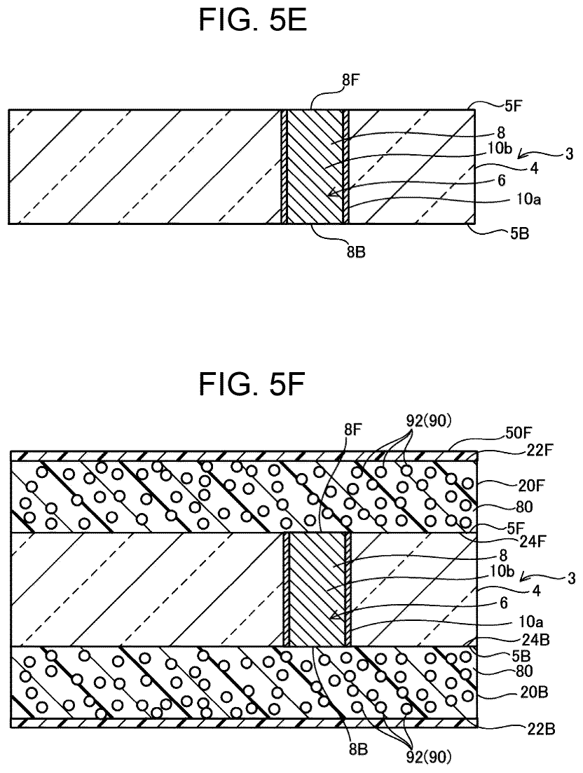

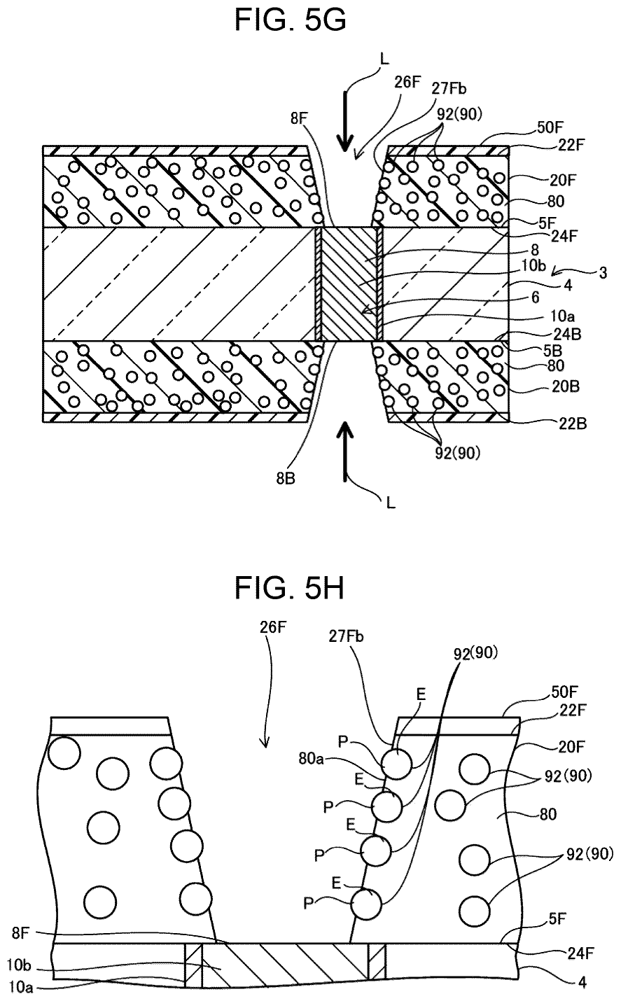

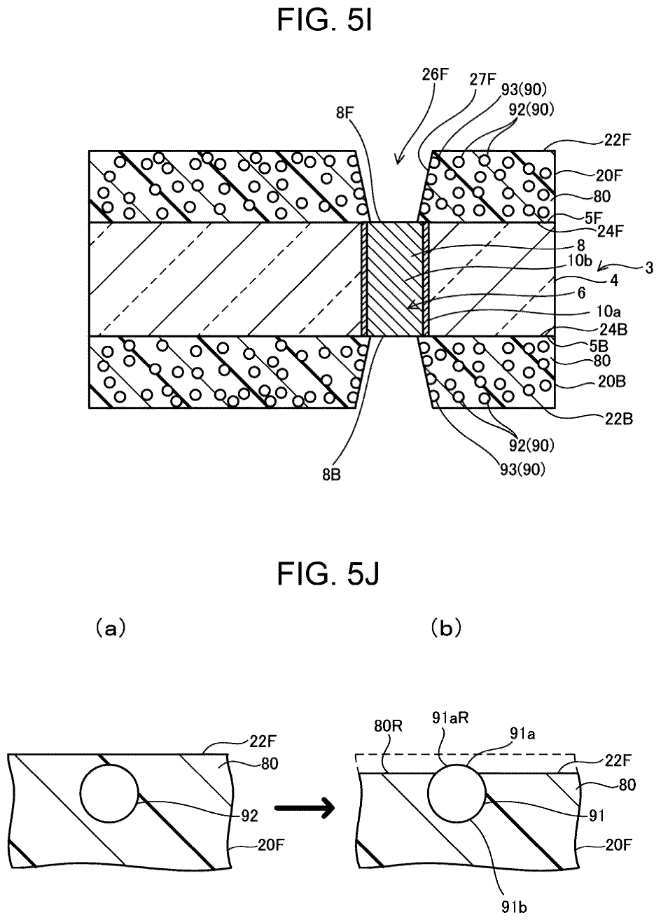

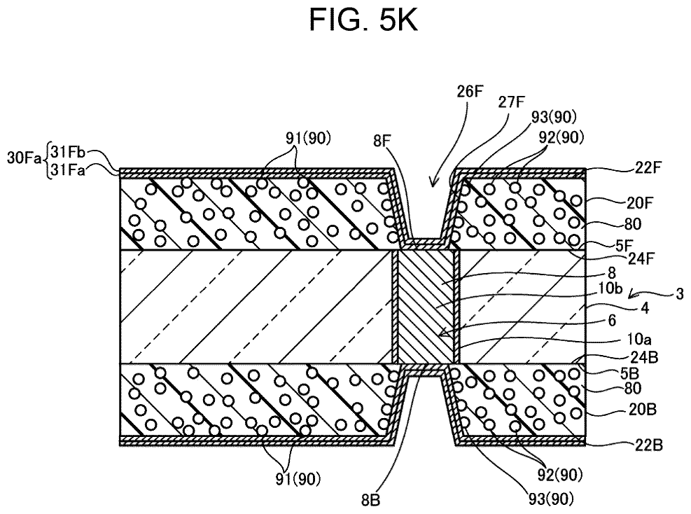

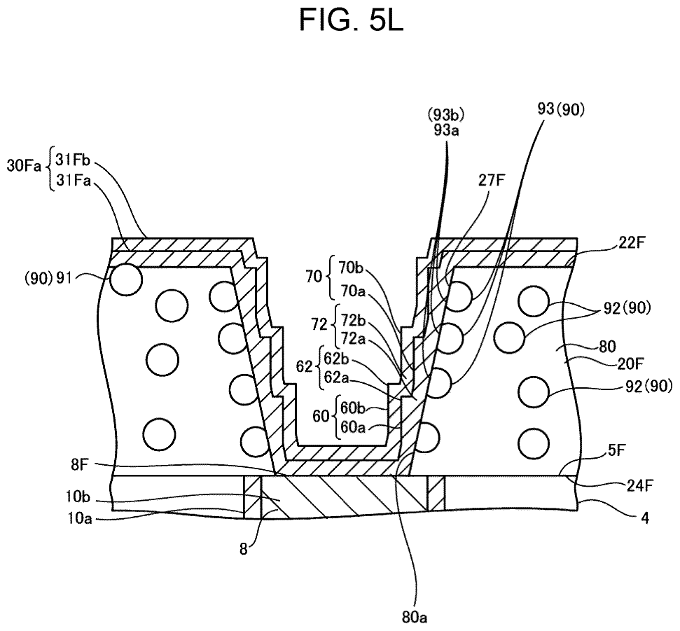

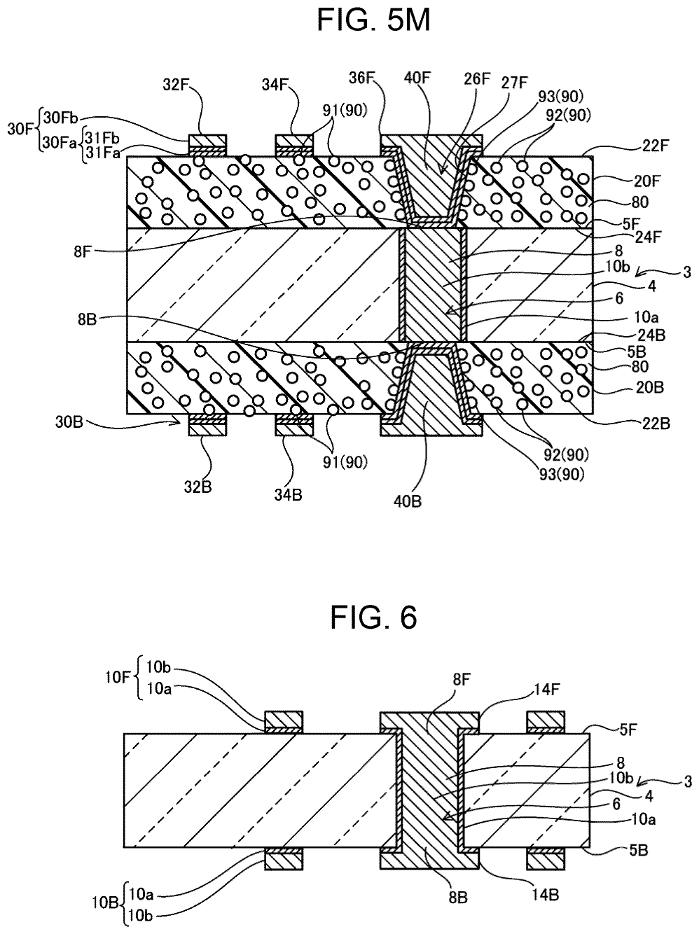

FIGS. 5A-5M illustrate a method for manufacturing the wiring substrate 2 of the embodiment. FIGS. 5A-5G, 5I, 5K, and 5M are cross-sectional views. FIGS. 5H, 5J, and 5L are enlarged cross-sectional views. FIG. 5A illustrates the glass substrate 4. The substrate 4 has the front surface (5F) and the back surface (5B). As illustrated in FIG. 5B, the through holes 6 each extending from the front surface (5F) to the back surface (5B) are formed. The through holes 6 penetrate the substrate 4. Laser is irradiated from the front surface (5F) side of the substrate 4. After that, the substrate 4 is immersed in a hydrofluoric acid. The through holes 6 are formed.

As illustrated in FIG. 5C, the seed layer (10a) is formed. The seed layer (10a) is formed by electroless plating. The seed layer (10a) is formed on the inner wall surfaces of the through holes 6, on the front surface (5F), and on the back surface (5B).

As illustrated in FIG. 5D, the electrolytic plating layer (10b) is formed. The electrolytic plating layer (10b) is formed on the seed layer (10a). The electrolytic plating layer (10b) fills the through holes 6.

As illustrated in FIG. 5E, the electrolytic plating layer (10b) and seed layer (10a) on the front surface (5F) are removed by polishing. The electrolytic plating layer (10b) and the seed layer (10a) on the back surface (5B) are removed by polishing. The front surface (5F) and the back surface (5B) of the substrate 4 are exposed. The through-hole conductors 8 are formed by the seed layer (10a) on the inner wall surfaces of the through holes 6 and the electrolytic plating layer (10b) on the seed layer (10a). The upper ends (8F) of the through-hole conductors 8 are exposed from the front surface (5F). The lower ends (8B) of the through-hole conductors 8 are exposed from the back surface (5B). Surfaces forming the upper ends (8F) and the front surface (5F) form the same flat surface. Surfaces forming the lower ends (8B) and the back surface (5B) form the same flat surface. The core substrate 3 is formed. The core substrate 3 has no conductor circuit on the front surface (5F). The core substrate 3 has no conductor circuit on the back surface (5B).

The front side build-up layer (300F) and the back side build-up layer (300B) are formed on core substrate 3 using similar methods. The method for forming the front side build-up layer (300F) is described below. The back side build-up layer (300B) is also depicted in the drawings.

As illustrated in FIG. 5F, the first resin insulating layer (20F) and a protective film (50F) are formed on the front surface (5F) of the substrate 4 and on the upper ends (8F). The second surface (24F) of the first resin insulating layer (20F) faces the front surface (5F) of the substrate 4. The protective film (50F) is formed on the first surface (22F) of the first resin insulating layer (20F). The first resin insulating layer (20F) contains the resin 80 and the inorganic particles 90 (the second inorganic particles 92). The inorganic particles 90 are embedded in the resin 80. The first surface (22F) of the first resin insulating layer (20F) is formed only of the resin 80. No inorganic particles 90 are exposed from the first surface (22F). The first surface (22F) does not include surfaces of the inorganic particles 90. No unevenness is formed on the first surface (22F) of the first resin insulating layer (20F). The first resin insulating layer (20F) is formed on a flat surface formed by the front surface (5F) and the upper ends (8F). Therefore, the first surface (22F) is formed as a substantially flat surface. The front surface (5F) and the first surface (22F) are substantially parallel.

As illustrated in FIG. 5G, laser (L) is irradiated from above the protective film (50F). The laser (L) penetrates the protective film (50F) and the first resin insulating layer (20F) at the same time. The first openings (26F) for the via conductors reaching the upper ends (8F) of the through-hole conductors 8 are formed. The laser (L) is, for example, UV laser, or CO₂ laser. The upper ends (8F) of the through-hole conductors 8 are exposed from the first openings (26F). When the first openings (26F) are formed, the first surface (22F) is covered by the protective film (50F). When the first openings (26F) are formed, even when the resin scatters, adherence of the resin to the first surface (22F) is suppressed.

The first surface (22F) is excellent in flatness. When the laser (L) is irradiated to the first surface (22F), the laser (L) is unlikely to be diffusely reflected. When each of the first openings (26F) is formed, a focus position of the laser (L) is likely to match. The embodiment allows via conductor openings having small diameters to be formed. The diameters of the via conductor openings are substantially equal to each other. For example, the embodiment allows via conductor openings having diameters of 15 μm or more and 35 μm or less to be formed. The diameters are measured on the first surface (22F).

FIG. 5H illustrates an inner wall surface (27Fb) of each of the first openings (26F) after the laser irradiation. The inner wall surface (27Fb) is formed of the resin 80 and the inorganic particles 90 protruding from the resin 80. In order to control a shape of the inner wall surface, the inner wall surface (27Fb) after the laser irradiation is treated. It is preferable to selectively remove the inorganic particles 90 protruding from the resin 80. As a result, the third inorganic particles 93 are formed from the inorganic particles 90. For example, the inorganic particles 90 protruding from the resin 80 are selectively removed by treating the inner wall surface (27Fb) after the laser irradiation with a chemical. Or, the inorganic particles 90 protruding from the resin 80 are selectively removed by treating the inner wall surface (27Fb) after the laser irradiation with plasma. The selectively removing includes that an etching rate of the inorganic particles 90 is greater than an etching rate of the resin 80. For example, a difference in etching rate between the two is 10 or more times. Or, the difference in etching rate between the two is 50 or more times. Or, the difference in etching rate between the two is 100 or more times. By treating the inner wall surface (27Fb) after the laser irradiation, the third inorganic particles 93 having the flat parts (93a) are obtained. By controlling conditions for treating the inner wall surface (27Fb) after the laser irradiation, the embodiment allows the shape of the inner wall surface (27F) to be controlled. Examples of the conditions are a temperature, a concentration, a time, a type of gas, and a pressure. The etching rate of the inorganic particles 90 and the etching rate of the resin are controlled.

By irradiating the first resin insulating layer (20F) with the laser (L), some of the second inorganic particles 92 embedded in the resin 80 form the inner wall surface (27Fb) after the laser irradiation. The second inorganic particles 92 forming the inner wall surface (27Fb) after the laser irradiation are each formed of a protruding portion (P) protruding from the resin 80 and a portion (E) embedded in the resin 80. The inorganic particles having the protruding portions (P) are referred to as protruding particles. For example, regarding the protruding particles, the protruding portions (P) are not removed at all. The inner wall surface (27Fb) after the laser irradiation is treated. For example, the inner wall surface (27Fb) is treated with plasma of a gas containing tetrafluoromethane. The protruding portions (P) are selectively removed to form the inner wall surface (27F) of the embodiment. The third inorganic particles 93 are formed from the second inorganic particles 92. By selectively removing the protruding portions (P), the third inorganic particles 93 having the flat parts (93a) are formed. The flat parts (93a) are flat surfaces. When the second inorganic particles 92 having spherical shapes are cut along a plane, the shapes of the third inorganic particles 93 are obtained. The third inorganic particles 93 each have a substantially spherical segment shape. The inner wall surface (27F) is formed of the flat parts (93a) and the surface (80a) of the resin 80, and the exposed surfaces (93b) of the flat parts (93a) and the surface (80a) of the resin 80 are substantially positioned on the same flat surface. As shown in FIG. 4, the steps 28 are formed at the boundary parts between the surface (80a) of the resin 80, which form the inner wall surface (27F), and the flat parts (93a) of the third inorganic particles 93. For example, when the seed layer (30Fa) is formed on the inner wall surface (27Fb) by sputtering, the protruding portions (P) inhibit growth of a sputtered film (sputtering-deposited film). For example, a continuous seed layer (30Fa) is not formed on the inner wall surface (27Fb). Or, the seed layer (30Fa) is increased in thickness. When the printed wiring board contains protruding particles, it is thought difficult to form fine conductor circuits. In the embodiment, the protruding portions (P) are removed. The embodiment allows the seed layer (30Fa) formed by sputtering to be reduced in thickness. Even when the seed layer (30Fa) formed by sputtering is thin, a continuous seed layer (30Fa) can be obtained. When the steps 28 are present, the surface (80a) of the resin is preferably recessed from the exposed surfaces (93b) of the flat parts (93a). It is also possible that the surface (80a) of the resin protrudes from the exposed surfaces (93b) of the flat parts (93a). By controlling the conditions for treating the inner wall surface (27Fb) after the laser irradiation, a size of unevenness or the sizes of the steps 28 are controlled.

Forming the first openings (26F) includes forming the inorganic particles 90 (the second inorganic particles 92) having the protruding portions (P). The protruding portions (P) protrude from the resin 80 that forms the inner wall surface (27Fb) of each of the first openings (26F). The third inorganic particles 93 are formed by removing the protruding portions (P) of the inorganic particles 90 (the second inorganic particles 92). The inner wall surface (27F) of each of the first openings (26F) includes the exposed surfaces (93b) of the third inorganic particles 93. The exposed surfaces (93b) of the third inorganic particles 93 are formed by removing the protruding portions (P).

Obtaining the shapes of the third inorganic particles 93 by cutting the second inorganic particles 92 having spherical shapes along a flat surface includes removing the protruding portions (P) of the inorganic particles 90. The actual inner wall surface (27F) of each of the first openings (26F) is a substantially curved surface. Since the flat parts (93a) are formed by removing the protruding portions (P), the exposed surfaces (93b) of the flat parts (93a) each include a curved surface. That is, forming a common surface with the flat parts (93a) and the resin 80 includes forming the inner wall surface (27F) formed with a substantially curved surface.

Insides of the first openings (26F) are cleaned. By cleaning the insides of the first openings (26F), resin residues generated when the first openings (26F) are formed are removed. The cleaning of the insides of the first openings (26F) is performed using plasma. That is, the cleaning is performed by a dry process. The cleaning includes a desmear treatment.

When the insides of the first openings (26F) are cleaned, the first surface (22F) of the resin insulating layer (20F) is covered by the protective film (50F). The first surface (22F) is not affected by the plasma. The first surface (22F) is formed only of the resin 80. No inorganic particles 90 are exposed from the first surface (22F). The first surface (22F) does not include surfaces of the inorganic particles 90. The first surface (22F) of the first resin insulating layer (20F) has no unevenness. The first surface (22F) is formed smooth.

When treating the inner wall surface (27Fb) after the laser irradiation includes cleaning the insides of the first openings (26F), cleaning the insides of the first openings (26F) can be omitted.

As illustrated in FIG. 5I, after cleaning the insides of the first openings (26F), the protective film (50F) is removed from the first resin insulating layer (20F). When treating the inner wall surface (27Fb) after the laser irradiation includes cleaning the insides of the first openings (26F), the protective film (50F) is removed from the first resin insulating layer (20F) after treating the inner wall surface (27Fb) after the laser irradiation. When the inner wall surface (27Fb) after the laser irradiation is treated, the protective film (50F) covers the first surface (22F) of the first resin insulating layer (20F). After the protective film (50F) is removed, the first surface (22F) of the first resin insulating layer (20F) is not roughened.

After removing the protective film (50F), the first surface (22F) of the first resin insulating layer (20F) is cleaned. The resin 80 forming the first surface (22F) is removed by a dry process. For example, the first surface (22F) of the first resin insulating layer (20F) is cleaned by reverse sputtering. For example, cleaning the first surface (22F) of the first resin insulating layer (20F) is performed by sputtering using argon gas (argon sputtering). FIGS. 5J(a) and 5J(b) schematically illustrate the first surface (22F) of the first resin insulating layer (20F) before and after the cleaning. As illustrated in FIGS. 5J(a) and 5J(b), about 20 nm of the resin 80 forming the first resin insulating layer (20F) is removed by the cleaning by sputtering or the like. For example, an adhesive used to adhere the protective film (50F) to the first resin insulating layer (20F) is removed. By the cleaning, the resin 80 is selectively removed. The resin 80 is reduced in thickness. Some of the inorganic particles 90 (the second inorganic particles 92) are partially exposed from the upper surface of the resin 80 by the cleaning. The first inorganic particles 91 are obtained by exposing the second inorganic particles 92 embedded in the resin 80 from the upper surface of the resin 80. The first inorganic particles 91 are formed from the second inorganic particles 92. The first inorganic particles 91 and the second inorganic particles 92 have the same shape. Both have a spherical shape. As illustrated in FIG. 5J(b), the first inorganic particles 91 are each formed of a first portion (91a) protruding from the resin 80 and a second portion (91b) embedded in the resin 80. The first surface (22F) of the first resin insulating layer (20F) is formed of the upper surface (80R) of the resin 80 and the exposed surfaces (91aR) of the first portions (91a) protruding from the upper surface (80R) of the resin 80. By the cleaning, the exposed surfaces (91aR) of the first portions (91a) are exposed. The first surface (22F) of the first resin insulating layer (20F) is not roughened. Therefore, substantially no recesses are formed on the first surface (22F). The first surface (22F) has substantially no recesses. The upper surface (80R) of the resin 80 is substantially flat. The upper surface (80R) of the resin 80 has no recesses.

The ratio (R) is calculated, for example, using the cross-sectional view of the first inorganic particles 91 illustrated in FIG. 5J(b). FIG. 5J(b) is obtained by cutting the first resin insulating layer (20F) along a plane perpendicular to the upper surface (80R). In FIG. 5J(b), the first conductor layer (30F) is omitted. In FIG. 5J(b), the first conductor layer (30F) is formed on the first inorganic particles 91. In FIG. 5J(b), the exposed surfaces (91aR) are covered by the first conductor layer (30F). Using FIG. 5J(b), a cross-sectional area (91aS) of the first portions (91a) is determined. Similarly, a cross-sectional area (91S) of the first inorganic particles 91 is obtained. For example, the ratio (R) is represented by a ratio of the cross-sectional area (91aS) to the cross-sectional area (91S) ((the cross-sectional area (91aS) of the first portions (91a))/(the cross-sectional area (91S) of the first inorganic particles 91)). For example, 50 first inorganic particles 91 are observed when the ratio (R) is evaluated. Fifty first inorganic particles 91 satisfy the ratio (R).

As illustrated in FIG. 5K, the seed layer (30Fa) is formed on the first surface (22F) of the first resin insulating layer (20F). The seed layer (30Fa) is formed by sputtering. The formation of the seed layer (30Fa) is performed by a dry process. The seed layer (30Fa) is also formed on the upper ends (8F) of the through-hole conductors 8 exposed from the first openings (26F) and on the inner wall surfaces (27F) of the first openings (26F). The seed layer (30Fa) is mainly formed of copper. The first layer (31Fa) is formed on the first surface (22F) by sputtering. The first layer (31Fa) is formed by sputtering on the inner wall surfaces (27F) exposed from the first openings (26F) and on the upper ends (8F) of the through-hole conductors 8. The second layer (31Fb) is formed on the first layer (31Fa) by sputtering. The first layer (31Fa) is formed of an alloy containing copper, aluminum, and a specific metal (for example, silicon). The second layer (31Fb) is formed of copper.

As illustrated in FIG. 5L, the first layer (31Fa) formed on the inner wall surface (27F) has the first film (60a) and the second film (70a). The first film (60a) and the second film (70a) are formed at the same time. The first film (60a) and the second film (70a) are electrically connected to each other. A leading end (62a) of the first film (60a) is formed on a trailing end (72a) of the second film (70a). The first layer (31Fa) formed on the inner wall surface (27F) has a substantially step-shaped cross section. Examples of sputtering conditions are described below. A distance between a target and the first surface (22F) of the first resin insulating layer (20F) is 50 mm or more and 250 mm or less. A voltage is 15 eV or more and 50 eV or less. A gas concentration is 0.1 Pa or more and 1.0 Pa or less.

The second layer (31Fb) formed on the first layer (31Fa) covering the inner wall surface (27F) has the first film (60b) and the second film (70b). The first film (60b) and the second film (70b) are formed at the same time. The first film (60b) and the second film (70b) are electrically connected to each other. A leading end (62b) of the first film (60b) is formed on a trailing end (72b) of the second film (70b). The second layer (31Fb) formed on the inner wall surface (27F) has a substantially step-shaped cross section. Sputtering conditions are substantially the same as those described above.

The inner wall surface (27F) of the embodiment is formed of the surface (80a) of the resin 80 and the exposed surfaces (93b) of the third inorganic particles 93. These surfaces form a substantially common surface. The surface (80a) of the resin and the exposed surfaces (93b) are formed of different materials. And, the first layer (31Fa) is formed by sputtering. It is thought that the growth of the first layer (31Fa) formed on the surface (80a) of the resin 80 and the growth of the first layer (31Fa) formed on the exposed surfaces (93b) are different from each other. It is thought that the growth of the seed layer (30Fa) formed on the surface (80a) of the resin 80 and the growth of the seed layer (30Fa) formed on the exposed surfaces (93b) are different from each other. Therefore, in the embodiment, it is thought that the first film (60a) and the second film (70a) are formed. It is thought that the leading end (62a) of the first film (60a) is formed on the trailing end (72a) of the second film (70a). It is thought that the first layer (31Fa) has a substantially step-shaped cross section. It is thought that the second layer (31Fb) follows the first layer (31Fa). Therefore, it is thought that the second layer (31Fb) has the first film (60b) and the second film (70b). It is thought that the leading end (62b) of the first film (60b) of the second layer (31Fb) is formed on the trailing end (72b) of the second film (70b) of the second layer (31Fb). It is thought that the second layer (31Fb) has a substantially step-shaped cross section. Similarly, it is thought that the seed layer (30Fa) has the first film 60 and the second film 70. It is thought that the leading end 62 of the first film 60 of the seed layer (30Fa) is formed on the trailing end 72 of the second film 70 of the seed layer (30Fa). It is thought that the seed layer (30Fa) has a substantially step-shaped cross section.

When the inner wall surface (27F) has the steps 28 shown in FIG. 4, the first layer (31Fa) having the first film (60a) and the second film (70a) can be easily formed by sputtering. The embodiment allows the seed layer (30Fa) having the first film 60 and the second film 70 to be easily formed. The embodiment allows the leading end (62a) of the first film (60a) to be formed on the trailing end (72a) of the second film (70a). The embodiment allows the leading end 60 of the first film 60 to be formed on the trailing end 72 of the second film 70. The embodiment allows the first layer (31Fa) having a substantially stepped shape to be easily formed. The embodiment allows the seed layer (30Fa) having a substantially stepped shape to be easily formed.

The first layer (31Fa) on the inner wall surface (27F) is formed on the substantially smooth inner wall surface (27F). Therefore, in the embodiment, the first film (60a) of the first layer (31Fa) and the second film (70a) of the first layer (31Fa) can be formed to have substantially smooth surfaces. Similarly, the first film (60b) of the second layer (31Fb) and the second film (70b) of the second layer (31Fb) can be formed to have substantially smooth surfaces. The first film 60 of the seed layer (30Fa) and the second film 70 of the seed layer (30Fa) can be formed to have substantially smooth surfaces. Since the surfaces are smooth, the embodiment allows transmission loss to be reduced.

The first layer (31Fa) of the seed layer (30Fa) is formed of an alloy containing copper and aluminum. Aluminum has high ductility and high malleability. Therefore, adhesion between the first resin insulating layer (20F) and the first layer (31Fa) is high. It is thought that, even when the first resin insulating layer (20F) expands and contracts due to heat cycles, the seed layer (30Fa) containing aluminum can follow the expansion and contraction. Even when the first surface (22F) is smooth, the seed layer (30Fa) is unlikely to peel off from the first resin insulating layer (20F). It is thought that aluminum is easily oxidized. It is thought that, when the third inorganic particles 93 are inorganic particles 90 containing oxygen (oxygen elements), the first layer (31Fa) formed on the inner wall surface (27F) of each of the first openings (26F) adheres to the third inorganic particles 93 via the oxygen in the inorganic particles 90 forming the inner wall surface (27F). The first layer (31Fa) is strongly bonded to the inner wall surface (27F). The embodiment allows adhesion between the inner wall surface (27F) of each of the first openings (26F) and the first layer (31Fa) to be increased. The seed layer (30Fa) is unlikely to peel off from the inner wall surface (27F). It is preferable that the inorganic particles 90 forming the inner wall surface (27F) contain oxygen elements. When the third inorganic particles (93) are glass particles and the first layer (31Fa) further contains silicon, both of them contain silicon. In this case, the first layer (31Fa) is formed of an alloy containing copper, aluminum, and silicon. It is thought that the two are strongly bonded to each other via silicon. Therefore, it is thought that adhesion between the first layer (31Fa) and the third inorganic particles 93 is further improved.

The first surface (22F) is excellent in flatness. When the seed layer (30Fa) is formed on the first surface (22F) by sputtering, a distance between a target and the first surface (22F) is substantially constant. The embodiment allows a seed layer (30Fa) having a substantially uniform thickness to be formed.

The first layer (31Fa) of the seed layer (30Fa) is in contact with the exposed surfaces (91aR) of the first portions (91a) of the first inorganic particles 91 that form the first surface (22F) of the first resin insulating layer (20F). When the first layer (31Fa) contains aluminum and the first inorganic particles 91 contain oxygen, it is thought that adhesion between the first layer (31Fa) and the first inorganic particles 91 is improved. Examples of the inorganic particles 90 (such as the first inorganic particles) containing oxygen are glass particles and alumina particles. Therefore, when the first layer (31Fa) is formed of an alloy containing copper and aluminum, even when the first surface (22F) of the first resin insulating layer (20F) has substantially no recesses, the first layer (31Fa) is unlikely to peel off from the first resin insulating layer (20F). A content of aluminum in the first layer (31Fa) is 1.0 at % or more and 15.0 at % or less. When the inorganic particles including the first inorganic particles 91 (the first inorganic particles 91, the second inorganic particles 92, and the third inorganic particles 93) are glass particles and the first layer (31Fa) further contains silicon, both of them contain silicon. In this case, the first layer (31Fa) is formed of an alloy containing copper, aluminum, and silicon. A content of silicon is 0.5 at % or more and 10.0 at % or less. It is thought that the two are strongly bonded to each other via silicon. Therefore, it is thought that adhesion between the first layer (31Fa) and the inorganic particles including the first inorganic particles 91 is further improved. The embodiment allows fine first signal wiring (32F) and second signal wiring (34F) to be formed. The fine first signal wiring (32F) and second signal wiring (34F) each have a width of 1 μm or more and 3 μm or less. Even when the wiring substrate 2 having the fine first signal wiring (32F) and second signal wiring (34F) is subjected to a thermal shock, the first signal wiring (32F) and second signal wiring (34F) are unlikely to peel off from the first resin insulating layer (20F).

A plating resist is formed on the seed layer (30Fa). The plating resist has openings for forming the first signal wiring (32F), the second signal wiring (34F), and the lands (36F). When the first surface (22F) has recesses, air caused by the recesses is likely to be trapped between the plating resist and the seed layer (30Fa). However, in the embodiment, the first surface (22F) has substantially no recesses. Therefore, the seed layer (30Fa) on the first surface (22F) is formed substantially flat. The seed layer (30Fa) has substantially no recesses. Air is unlikely to remain between the plating resist and the seed layer (30Fa). A contact area between the plating resist and the seed layer (30Fa) is large. Even when a width of the plating resist for forming a space between the signal wirings is 10 μm or less, the plating resist is unlikely to peel off from an upper surface of the seed layer (30Fa). Even when the width of the plating resist is 3 μm or more and 8 μm or less, the embodiment allows the plating resist to be formed on the seed layer (30Fa). Even when the width of the plating resist is 6 μm or less, the plating resist is unlikely to peel off from the seed layer (30Fa).

The electrolytic plating layer (30Fb) is formed on the seed layer (30Fa) exposed from the plating resist. The electrolytic plating layer (30Fb) fills the first openings (26F). The first signal wiring (32F), the second signal wiring (34F), and the lands (36F) are formed by the seed layer (30Fa) and the electrolytic plating layer (30Fb) on the first surface (22F). The first conductor layer (30F) is formed. The first via conductors (40F) are formed by the seed layer (30Fa) and electrolytic plating layer (30Fb) in the first openings (26F). The first via conductors (40F) connect the through-hole conductors 8 and the lands (36F). The first signal wiring (32F) and the second signal wiring (34F) form a pair wiring.

The plating resist is removed. The seed layer (30Fa) exposed from the electrolytic plating layer (30Fb) is removed. As illustrated in FIG. 5M, the first conductor layer (30F) and the first via conductors (40F) are formed at the same time.

The second resin insulating layer (120F) is formed on the first surface (22F) of the first resin insulating layer (20F) and on the first conductor layer (30F). The second conductor layer (130F) is formed on the first surface (122F) of the second resin insulating layer (120F). The second via conductors (140F) are formed in the second openings (126F) of the second resin insulating layer (120F). The second resin insulating layer (120F) is formed using the same method as the first resin insulating layer (20F). The second conductor layer (130F) is formed using the same method as the first conductor layer (30F). The second via conductors (140F) are formed using the same method as the first via conductors (40F). The wiring substrate 2 of the embodiment is obtained.

The core substrate 3 of the wiring substrate 2 of the embodiment includes the glass substrate 4. The glass substrate 4 is excellent in flatness. The first surfaces (22F, 22B) of the first resin insulating layers (20F, 20B) are excellent in flatness and smoothness. The embodiment allows fine signal wirings (32F, 32B, 34F, 34B) to be formed on the first surfaces (22F, 22B) of the first resin insulating layers (20F, 20B). The first surfaces (122F, 122B) of the second resin insulating layers (120F, 120B) are similar to the first surfaces (22F, 22B) of the first resin insulating layers (20F, 20B). Therefore, the embodiment allows fine signal wirings (132F, 132B, 134F, 134B) to be formed on the first surfaces (122F, 122B) of the second resin insulating layers (120F, 120B). The L/S of a signal wiring formed according to the embodiment is, for example, less than (5 μm)/(5 μm). The L/S of a signal wiring is preferably (1.5 μm)/(1.5 μm) or more and (3.5 μm)/(3.5 μm) or less. L means a width of a signal wiring, and S means a width of a space between adjacent signal wirings.

In the embodiment, the first layer formed on the inner wall surface of each of the via conductor openings is formed by sputtering. The resin insulating layer on the glass substrate 4 is unlikely to warp. Gaps that inhibit growth of a sputtered film are unlikely to occur between the resin 80 and third inorganic particles 93, which form the inner wall surface of each of the via conductor openings. The inner wall surface of each of the openings is unlikely to have large undulation or large unevenness. Even when the sputtered film on the inner wall surface has a small thickness, the embodiment allows a continuous sputtered film to be formed.

The inner wall surface of each of the via conductor openings (the first openings and the second openings) is formed of the resin 80 and the exposed surfaces (93b) of the flat parts (93a) of the third inorganic particles 93. It is thought that, when the first layer is formed, particles forming the sputtered film adhere to the third inorganic particles 93. It is thought that the particles forming the sputtered film are not embedded in the third inorganic particles 93. The embodiment allows a thin and continuous seed layer to be formed on the inner wall surface. The embodiment allows a thin and continuous seed layer to be formed on the first surface and the inner wall surface. When the seed layer is removed, an etching amount is small. Therefore, an etching amount of the electrolytic plating layer is small. A signal wiring has a width as designed. The embodiment allows fine signal wirings to be formed. A high quality wiring substrate 2 is provided.

In the wiring substrate 2 of the embodiment, the first surface (22F) of the first resin insulating layer (20F) is formed of the upper surface (80R) of the resin 80 and the exposed surfaces (91aR) of the first portions (91a) exposed from the upper surface (80R) of the resin 80. The first surface (22F) and the upper surface (80R) have substantially no recesses. Therefore, when the seed layer (30Fa) is formed on the first resin insulating layer (20F) by sputtering, the embodiment allows a continuous seed layer (30Fa) to be formed even when a sputtered film is thin. The seed layer (30Fa) is formed thin. When the seed layer (30Fa) is removed, an etching amount is small. Therefore, an etching amount of the electrolytic plating layer (30Fb) is small. A signal wiring has a width as designed. Fine wirings are formed. A high quality wiring substrate 2 is provided.

The embodiment allows the first layer (31Fa) formed of an alloy containing copper and aluminum to be reduced in thickness. In the signal wirings, a content rate of aluminum is low and a content rate of copper is high. The embodiment can provide low-resistance signal wirings. The embodiment can provide signal wirings with high adhesion to the resin insulating layers.

In the wiring substrate 2 of the embodiment, the first surfaces (22F, 22B) of the first resin insulating layers (20F, 20B) have substantially no recesses. An increase in standard deviation of a relative permittivity in a portion near the first surfaces (22F, 22B) of the first resin insulating layers (20F, 20B) is suppressed. The relative permittivity of the first surfaces (22F, 22B) does not significantly vary depending on a location. Even when the first signal wiring (32F, 32B) and the second signal wiring (34F, 34B) are in contact with the first surface (22F, 22B), the embodiment allows a difference in propagation speed of an electrical signal between the first signal wiring (32F, 32B) and the second signal wiring (34F, 34B) to be reduced. Therefore, in the wiring substrate 2 of the embodiment, noise is suppressed. Even when a logic IC is mounted on the wiring substrate 2 of the embodiment, data transmitted via the first signal wiring (32F, 32B) and data transmitted via the second signal wiring (34F, 34B) arrive at the logic IC substantially without delay. In the embodiment, malfunction of the logic IC can be suppressed. Even when a length of the first signal wiring (32F, 32B) and a length of the second signal wiring (34F, 34B) are 5 mm or more, the embodiment allows a difference in the propagation speed between the two to be reduced. Even when the length of the first signal wiring (32F, 32B) and the length of the second signal wiring (34F, 34B) are 10 mm or more and 20 mm or less, the embodiment allows malfunction of the logic IC to be suppressed. The first surfaces (122F, 122B) of the second resin insulating layers (120F, 120B) are similar to the first surfaces (22F, 22B) of the first resin insulating layers (20F, 20B). Therefore, the first signal wirings (132F, 132B) and the second signal wirings (134F, 134B) have similar effects as the first signal wirings (32F, 32B) and the second signal wirings (34F, 34B). A high quality wiring substrate 2 is provided.

In the embodiment, a part of the first film of the seed layer that covers the inner wall surface of each of the via conductor openings (the first openings and the second openings) is formed on the second film. The first film and the second film partially overlap. Therefore, strength of the seed layer is high. Since the glass core substrate and the resin insulating layer are significantly different in thermal expansion coefficient, when the wiring substrate 2 is subjected to heat cycles, a stress occurs between the resin insulating layer and the seed layer. Even when the resin insulating layer expands and contracts due to heat cycles, it is thought that the stress can be relaxed by partial overlapping the first film and the second film. Or, it is thought that the seed layer can follow the expansion and contraction. Therefore, the seed layer is unlikely to break. The seed layer is formed of the substantially smooth first film and the substantially smooth second film. Therefore, transmission loss is low when a high frequency signal is transmitted. A high quality wiring substrate 2 is provided.

When the first layer contains silicon as the specific metal and the inorganic particles are glass particles, the first layer and the third inorganic particles 93 on the inner wall surface contain silicon. The first layer on the first surface and the first inorganic particles 91 contain silicon. It is thought that the two are strongly bonded to each other via silicon. The seed layer is unlikely to peel off from the inner wall surface. The seed layer is unlikely to peel off from the first surface. Therefore, the first layer is preferably formed of an alloy containing copper, aluminum, and silicon.

When the first layer contains aluminum and the inorganic particles 90 (the first inorganic particles 91, the second inorganic particles 92, and the third inorganic particles 93) contain oxygen, it is thought that the first layer and the inorganic particles 90 (oxygen-containing inorganic particles such as glass particles) are strongly bonded to each other. When the first layer contains aluminum and the inorganic particles 90 contain oxygen, the first layer does not need to contain the specific metal. In this case, the first layer is formed of copper, aluminum, and impurities.

### First Alternative Example

In a first alternative example of the embodiment, the specific metal contained in the alloy forming the first layer is at least one of nickel, zinc, gallium, silicon, and magnesium.

### Second Alternative Example

In a second alternative example of the embodiment, the alloy forming the first layer does not contain carbon.

### Third Alternative Example

In a third alternative example of the embodiment, the alloy forming the first layer does not contain oxygen.

### Modified Example

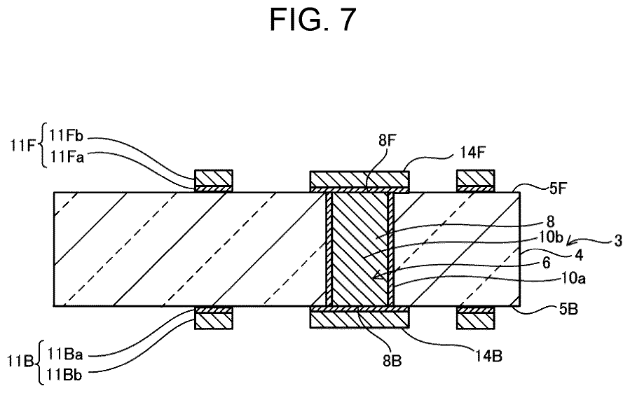

Similar to the embodiment, wiring substrates of modified examples each include a core substrate 3, a front side build-up layer (300F), and a back side build-up layer (300B). The core substrate 3 of the embodiment is different from the core substrates 3 of the modified examples. The front side build-up layer (300F) of the embodiment is the same as the front side build-up layer (300F) of each of the modified examples. The back side build-up layer (300B) of the embodiment is the same as the back side build-up layer (300B) of each of the modified examples. Cross-sections of the core substrates 3 of the modified examples are respectively illustrated in FIGS. 6 and 7. As illustrated in FIGS. 6 and 7, the core substrates 3 of the modified examples respectively have conductor layers (10F, 11F) on the front surface (5F) of the glass substrate 4. The conductor layers (10F, 11F) each include lands (14F) covering the upper ends (8F) of the through-hole conductors 8. Further, the core substrates 3 of the modified examples respectively have conductor layers (10B, 11B) on the back surface (5B) of the substrate 4. The conductor layers (10B, 11B) each include lands (14B) covering the lower ends (8B) of the through-hole conductors 8. The lands (14F) and the lands (14B) are electrically connected by the through-hole conductors 8. The core substrate 3 of the embodiment has no conductor layer on the front surface (5F) and no conductor layer on the back surface (5B).

In the modified examples, the front side resin insulating layer (resin insulating layer directly above the core substrate) forming the front side build-up layer (300F) is formed on the conductor layer (10F, 11F) and the front surface (5F). The resin insulating layer (first resin insulating layer (20F)) directly above the core substrate has via conductor openings (first openings (26F)) reaching the lands (14F). Via conductors (first via conductors (40F)) similar to those of the embodiment are formed in the via conductor openings. Since the via conductors penetrating the resin insulating layer directly above the core substrate reach the lands (14F), the seed layer (first layer (31Fa)) forming the via conductors is in contact with upper surfaces of the lands (14F) and inner wall surfaces of the openings. The via conductors penetrating the resin insulating layer directly above the core substrate are electrically connected to the through-hole conductors 8 via the lands (14F).

In the modified examples, the back side resin insulating layer (resin insulating layer directly below the core substrate) forming the back side build-up layer (300B) is formed on the conductor layer (10B, 11B) and the back surface (5B). The resin insulating layer (first resin insulating layer (20B)) directly below the core substrate has via conductor openings (first openings) reaching the lands (14B). Via conductors (first via conductors (40B)) similar to those of the embodiment are formed in the via conductor openings. Since the via conductors penetrating the resin insulating layer directly below the core substrate reach the lands (14B), the seed layer forming the via conductors is in contact with upper surfaces of the lands (14B) and inner wall surfaces of the openings. The via conductors penetrating the resin insulating layer directly below the core substrate are electrically connected to the through-hole conductors 8 via the lands (14B).

### Method for Manufacturing Wiring Substrate

The core substrate 3 illustrated in FIG. 6 is a core substrate 3 of a first example. A method for manufacturing the core substrate 3 of the first example is described below. An intermediate substrate illustrated in FIG. 5D is prepared. The conductor layer (10F) is formed on the front surface (5F) using a subtractive method. The conductor layer (10B) is formed on the back surface (5B). The core substrate 3 of the first example of the modified examples is obtained.

The conductor layer (10F) is formed of the seed layer (10a) and the electrolytic plating layer (10b) on the seed layer (10a). The conductor layer (10B) is formed of the seed layer (10a) and the electrolytic plating layer (10b) on the seed layer (10a). The seed layer (10a) is formed by electroless plating. The seed layer (10a) forming the conductor layer (10F), the seed layer (10a) forming the conductor layer (10B), and the seed layer (10a) forming the through-hole conductors 8 are common. The electrolytic plating layer (10b) forming the conductor layer (10F), the electrolytic plating layer (10b) forming the conductor layer (10B), and the electrolytic plating layer (10b) forming the through-hole conductors 8 are common. The conductor layers (10F, 10B) and the through-hole conductors 8 are formed at the same time. The through-hole conductors 8 and the lands (14F, 14B) are formed at the same time. The through-hole conductors 8 and the lands (14F, 14B) are integrally formed. There is no seed layer between the upper ends (8F) and the lands (14F). There is no seed layer between the lower ends (8B) and the lands (14B).

The core substrate 3 illustrated in FIG. 7 is a core substrate 3 of a second example. A method for manufacturing the core substrate 3 of the second example is described below. An intermediate substrate illustrated in FIG. 5E is prepared. Seed layers (11Fa, 11Ba) are respectively formed on the front surface (5F) and the back surface (5B). The seed layers (11Fa, 11Ba) are formed by electroless plating. It is also possible that the seed layers (11Fa, 11Ba) are formed by sputtering. The seed layer (11Fa) covers the front surface (5F) of the substrate 4 and the upper ends (8F) of the through-hole conductors 8. The seed layer (11Ba) covers the back surface (5B) of the substrate 4 and the lower ends (8B) of the through-hole conductors 8. Electrolytic plating layers (11Fb, 11Bb) are respectively formed on the seed layers (11Fa, 11Ba). After that, the conductor layers (11F, 11B) are formed using a subtractive method. The core substrate 3 of the second example of the modified examples is obtained.

The conductor layer (11F) is formed of the seed layer (11Fa) and the electrolytic plating layer (11Fb) on the seed layer (11Fa). The conductor layer (11B) is formed of the seed layer (11Ba) and the electrolytic plating layer (11Bb) on the seed layer (11Ba). The seed layer (11Fa) is formed on the front surface (5F) of the substrate 4. The seed layer (11Fa) covers the upper ends (8F) of the through-hole conductors 8. The seed layer (11Ba) is formed on the back surface (5B) of the substrate 4. The seed layer (11Ba) covers the lower ends (8B) of the through-hole conductors 8. The seed layers (11Fa, 11Ba) are formed by electroless plating. It is also possible that the seed layers (11Fa, 11Ba) are formed by sputtering. The seed layers (11Fa, 11Ba) that respectively form the conductor layers (11F, 11B) and the seed layer (10a) that forms the through-hole conductors 8 are different from each other. The electrolytic plating layers (11Fb, 11Bb) that respectively form the conductor layers (11F, 11B) and the electrolytic plating layer (10b) that forms the through-hole conductors 8 are different from each other. The conductor layers (11F, 11B) and the through-hole conductors 8 are separately formed. In the second example, the seed layer (11Fa) forming the lands (14F) exists between the electrolytic plating layer (10b) forming the upper ends (8F) and the electrolytic plating layer (11Fb) forming the lands (14F). The seed layer (11Ba) forming the lands (14B) exists between the electrolytic plating layer (10b) forming the lower ends (8B) and the electrolytic plating layer (11Bb) forming the lands (14B). In contrast, in the first example (FIG. 6), the electrolytic plating layer (10b) forming the upper ends (8F) and the electrolytic plating layer (10b) forming the lands (14F) are continuous. The electrolytic plating layer (10b) forming the lower ends (8B) and the electrolytic plating layer (10b) forming the lands (14B) are continuous.

The front side build-up layer (300F) and back side build-up layer (300B) are formed on each of the core substrates 3 of the modified examples in the same way as the embodiment.

In the present specification, the term “flat surface” is used with respect to the shape of the inner wall surface, the shapes of the flat parts (93a), and the shapes of the third inorganic particles 93. The meaning of the “flat surface” used with respect to these is illustrated in FIGS. 1 and 3A. That is, in FIGS. 1 and 3A, the inner wall surface is drawn substantially straight. The shape of the inner wall surface in FIGS. 1 and 3A is substantially a straight line. The term “flat surface” in the present specification includes a substantially straight line illustrated in a cross section. As illustrated in the cross sections of the third inorganic particles 93 in FIGS. 1 and 3A, in a cross section, cutting along a flat surface includes cutting along a straight line. The term “flat surface” in the present specification does not mean a perfect flat surface but includes a substantially flat surface. A substantially flat surface may include small unevenness.

Japanese Patent Application Laid-Open Publication No. 2015-133473 describes a multilayer substrate having a core formed of a glass material.

In Japanese Patent Application Laid-Open Publication No. 2015-133473, light transmittance of a first insulating layer formed of a glass material is controlled. As an example of a method for controlling the light transmittance, Japanese Patent Application Laid-Open Publication No. 2015-133473 describes that a coloring agent is contained in the first insulating layer. It is thought difficult for the first insulating layer formed of a glass material to uniformly contain a coloring agent.

A wiring substrate according to an embodiment of the present invention includes: a core substrate that has a glass substrate, a through hole penetrating the substrate, and a through-hole conductor formed in the through hole; a resin insulating layer that is formed on the core substrate, and has a first surface, a second surface on the opposite side with respect to the first surface, and a via conductor opening extending from the first surface to the second surface; a first conductor layer that is formed on the first surface of the resin insulating layer; and a via conductor that is formed in the opening and is electrically connected to the through-hole conductor. The first conductor layer and the via conductor are formed of a seed layer and an electrolytic plating layer formed on the seed layer. The seed layer is formed by sputtering. The resin insulating layer is formed of a resin and inorganic particles. The inorganic particles include first inorganic particles that are partially embedded in the resin and second inorganic particles that are embedded in the resin. The first inorganic particles are each formed of a first portion protruding from the resin and a second portion embedded in the resin. The first surface is formed by an upper surface of the resin and exposed surfaces of the first portions exposed from the upper surface of the resin.

In a wiring substrate according of an embodiment of the present invention, the core substrate includes the glass substrate. The glass substrate is excellent in flatness. Therefore, the first surface of the resin insulating layer is excellent in flatness. The first surface is excellent in smoothness. The embodiment allows fine wirings to be formed on the first surface of the resin insulating layer. In the embodiment, substantially no recesses are formed on the first surface of the resin insulating layer. Therefore, when a seed layer is formed by sputtering on the resin insulating layer, the embodiment allows a continuous seed layer to be formed even when a sputtered film is thin. As a result, when the seed layer is removed, the embodiment allows an etching amount to be reduced. The embodiment allows fine wirings to be formed on the resin insulating layer.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a core substrate comprising a glass substrate and a through-hole conductor penetrating through the glass substrate;
a resin insulating layer formed on the core substrate and having an opening extending through the resin insulating layer;
a conductor layer formed on a surface of the resin insulating layer and comprising a seed layer formed by sputtering and an electrolytic plating layer formed on the seed layer; and
a via conductor formed in the opening of the resin insulating layer such that the via conductor is configured to be electrically connected to the through-hole conductor in the core substrate and includes the seed layer and electrolytic plating layer extending from the conductor layer,
wherein the resin insulating layer includes resin and inorganic particles comprising first particles and second particles such that the first particles are partially embedded in the resin and that the second particles are embedded in the resin, and the resin insulating layer is formed such that the first particles have first portions protruding from the resin and second portions embedded in the resin respectively and that the surface includes the resin and exposed surfaces of the first portions exposed from the resin.

2. The wiring substrate according to claim 1, wherein the resin insulating layer is formed such that a ratio of a volume of the first portions to a volume of the first particles is greater than 0 and less than or equal to 0.4.

3. The wiring substrate according to claim 1, wherein the resin insulating layer is formed such that the inorganic particles include glass particles.

4. The wiring substrate according to claim 1, wherein the resin insulating layer is formed such that the inorganic particles include third particles having flat parts and that the flat parts of the third particles and the resin form an inner wall surface in the opening.

5. The wiring substrate according to claim 4, wherein the resin insulating layer is formed such that the flat parts of the third particles and the resin form substantially a common surface forming the inner wall surface in the opening.

6. The wiring substrate according to claim 4, wherein the resin insulating layer is formed such that each of the second particles has a spherical shape and that each of the third particles has a shape obtained by cutting the second particles with a plane.

7. The wiring substrate according to claim 1, wherein the resin insulating layer is formed such that the inorganic particles include oxygen.

8. The wiring substrate according to claim 1, wherein the conductor layer is formed such that the seed layer includes a first layer comprising an alloy and a second layer formed on the first layer and that the alloy in the first layer includes copper and aluminum.

9. The wiring substrate according to claim 8, wherein the conductor layer is formed such that the alloy in the first layer includes silicon.

10. The wiring substrate according to claim 1, wherein the conductor layer is formed such that the seed layer covering an inner wall surface in the opening of the resin insulating layer includes a first film and a second film and that a part of the first film is formed on the second film.

11. The wiring substrate according to claim 10, wherein the seed layer in the conductor layer is formed such that a leading end of the first film is formed on a trailing end of the second film.

12. The wiring substrate according to claim 10, wherein the seed layer in the conductor layer is formed such that the first film and the second film are formed in a same process.

13. The wiring substrate according to claim 10, wherein the seed layer in the conductor layer is formed such that the seed layer covering the inner wall surface in the opening of the resin insulating layer has a substantially step-shaped cross section.

14. The wiring substrate according to claim 2, wherein the conductor layer is formed such that the seed layer includes a first layer comprising an alloy and a second layer formed on the first layer and that the alloy in the first layer includes copper and aluminum.

15. The wiring substrate according to claim 14, wherein the conductor layer is formed such that the alloy in the first layer includes silicon.

16. The wiring substrate according to claim 2, wherein the conductor layer is formed such that the seed layer covering an inner wall surface in the opening of the resin insulating layer includes a first film and a second film and that a part of the first film is formed on the second film.

17. The wiring substrate according to claim 16, wherein the seed layer in the conductor layer is formed such that a leading end of the first film is formed on a trailing end of the second film.

18. A method of manufacturing a wiring substrate, comprising:
forming a core substrate comprising a glass substrate and a through-hole conductor penetrating through the glass substrate;
forming a resin insulating layer on the core substrate such that the resin insulating layer has an opening extending through the resin insulating layer;
forming a conductor layer on a surface of the resin insulating layer such that the conductor layer includes a seed layer formed by sputtering and an electrolytic plating layer formed on the seed layer; and
forming a via conductor in the opening of the resin insulating layer such that the via conductor is configured to be electrically connected to the through-hole conductor in the core substrate and includes the seed layer and electrolytic plating layer extending from the conductor layer,
wherein the resin insulating layer includes resin and inorganic particles comprising first particles and second particles such that the first particles are partially embedded in the resin and that the second particles are embedded in the resin, and the resin insulating layer is formed such that the first particles have first portions protruding from the resin and second portions embedded in the resin respectively and that the surface includes the resin and exposed surfaces of the first portions exposed from the resin.

19. The method of claim 18, wherein the resin insulating layer is formed such that the inorganic particles include third particles having flat parts and that the flat parts of the third particles and the resin form an inner wall surface in the opening.

20. The method of claim 19, wherein the forming of the resin insulating layer includes forming the inorganic particles having protruding portions such that the protruding portions protrude from an inner wall surface in the opening of the resin insulating layer, and removing the protruding portions of the inorganic particles such that the third particles are formed.
